(19) United States
(12) Patent Application Publication
(10) Pub. No.: US 2015/0262975 A1
(43) Pub. Date: Sep. 17, 2015

(54) MANUFACTURING METHOD OF SEMICONDUCTOR DEVICE AND SEMICONDUCTOR DEVICE

(71) Applicant: KABUSHIKI KAISHA TOSHIBA, Tokyo (JP)

(72) Inventor: Masatoshi KAWATO, Kameyama Mie (JP)

(21) Appl. No.: 14/475,559

(22) Filed: Sep. 2, 2014

(30) Foreign Application Priority Data
Mar. 14, 2014 (JP) 2014-052715

(51) Int. Cl. H01L 25/065; H01L 21/56; H01L 21/78; H01L 21/48; H01L 23/04; H01L 23/48; H01L 25/00; H01L 23/31; H01L 23/498; H01L 23/00; H01L 23/29

(52) U.S. Cl. CPC H01L 25/0657; H01L 24/11; H01L 21/563; H01L 21/78; H01L 21/4878; H01L 24/17; H01L 24/81; H01L 23/295; H01L 23/481; H01L 25/50; H01L 24/96; H01L 23/3107; H01L 23/49838; H01L 23/04; H01L 2924/186; H01L 2924/1438; H01L 2224/116; H01L 2224/11849; H01L 2924/37; H01L 2924/0665; H01L 2224/81345; H01L 2225/06517; H01L 2225/06541

(57) ABSTRACT

A semiconductor device manufacturing method includes mounting a stacked body on a first surface of a wiring substrate, the stacked body including a metal plate and semiconductor chips that are stacked on a part of the metal plate and located on the first surface side of the wiring substrate, forming a resin layer to seal the stacked body on the first surface of the wiring substrate, forming a first cut reaching the sealing resin layer by using a first dicing blade while cutting either the metal plate or the wiring substrate, the first cut surrounding the stacked body, and forming a second cut reaching the first cut using a second dicing blade while cutting the other of the metal plate and the wiring substrate to separate the wiring substrate in correspondence with the location of the stacked body, the second cut also surrounding the stacked body.

### CROSS-REFERENCE TO RELATED APPLICATION

This application is based upon and claims the benefit of priority from Japanese Patent Application No. 2014-052715, filed Mar. 14, 2014, the entire contents of which are incorporated herein by reference.

### FIELD

Embodiments described herein relate generally to a manufacturing method of a semiconductor device, and to a semiconductor device.

### BACKGROUND

Recently, there is increasing demand for miniaturization and speed increases of semiconductor devices as a result of ongoing development of communication technology and information processing technology. To meet this demand, development of a semiconductor package having a three-dimensional mounting structure is promoted. According to this type of semiconductor package, the wire lengths between respective components on a semiconductor device are shortened by adoption of the three-dimensional mounting structure where a plurality of semiconductor chips are stacked, so that the semiconductor device is operable at a higher operating frequency with high mounting area efficiency, i.e., greater processing power or memory capacity over a given surface area.

For example, in the field of semiconductor devices such as NAND flash memories, there is proposed a three-dimensional mounting structure where memory controllers and memory chips are stacked on the same wiring substrate for the purpose of miniaturization and speed increase. Examples of this type of three-dimensional mounting structure currently studied involve a stacked structure employing a TSV (through silicon via) system.

A semiconductor device having the stacked structure with TSV system is manufactured by the following steps. A plurality of semiconductor chips are stacked on a metal plate. Electric connection is established between the semiconductor chips by using through electrodes penetrating the semiconductor chips forming the stacked body. The stacked body on the metal plate is bonded to a wiring substrate. Sealing resin is injected into the space between the semiconductor chips and the wiring substrate to seal the stacked body. External connection terminals are formed on the wiring substrate. The respective wiring substrates are then diced into discrete pieces in correspondence with the location of the stacked bodies thereon.

In the dicing step, the wiring substrates are cut using a dicing blade, for example. In this case, projections called burrs are produced during cutting. The burrs produced by cutting may increase the thickness of the package, or cause short circuits therein. Accordingly, it is preferable that burrs produced during the dicing step are reduced to a minimum.

### DESCRIPTION OF THE DRAWINGS

FIG. 1 is a flowchart illustrating an example of a manufacturing method of a semiconductor device.

FIGS. 2A through 2C are cross-sectional views illustrating an example of a manufacturing method of a stacked body.

FIGS. 3A through 3C are cross-sectional views illustrating an example of the manufacturing method of the semiconductor device.

FIGS. 4A and 4B illustrate a first cutting step.

FIGS. 5A and 5B illustrate a second cutting step.

FIGS. 6A and 6B illustrate a structure example of the semiconductor device.

FIGS. 7A and 7B are cross-sectional views illustrating another example of the manufacturing method of the semiconductor device.

FIGS. 8A and 8B are cross-sectional views illustrating a further example of the manufacturing method of the semiconductor device.

FIG. 9 is a flowchart illustrating an example of a manufacturing method of a semiconductor device.

FIGS. 10A through 10C are cross-sectional views illustrating an example of the manufacturing method of the semiconductor device.

### DETAILED DESCRIPTION

In general, according to one embodiment, a technology is provided that is capable of reducing formation of burrs created during the cutting of a wiring substrate to which stacked bodies of semiconductor chips have been adhered.

According to one embodiment, a manufacturing method of a semiconductor device includes mounting a stacked body on a first surface of a wiring substrate. The stacked body includes a metal plate and semiconductor chips stacked on a part of the metal plate. The semiconductor chips are located on the first surface side of the wiring substrate. The method includes forming a sealing resin layer sealing the stacked body on the first surface of the wiring substrate. The method includes forming a first cut reaching the sealing resin layer by using a first dicing blade while cutting either the metal plate or the wiring substrate. The first cut surrounds the stacked body. The method includes forming a second cut reaching the first cut using a second dicing blade while cutting the other of the metal plate and the wiring substrate to separate the wiring substrate in correspondence with the stacked body. The second cut likewise surrounds the stacked body.

Exemplary embodiments are hereinafter described with reference to the drawings. The respective figures are only schematic illustrations, and the relationship between the thicknesses and the planar dimensions, and the ratios of the thicknesses of the respective layers, and other conditions are different from those in actual semiconductor devices in some cases. Substantially similar constituent elements in the respective embodiments are given similar reference numbers, and the explanation thereof is not repeated.

### First Embodiment

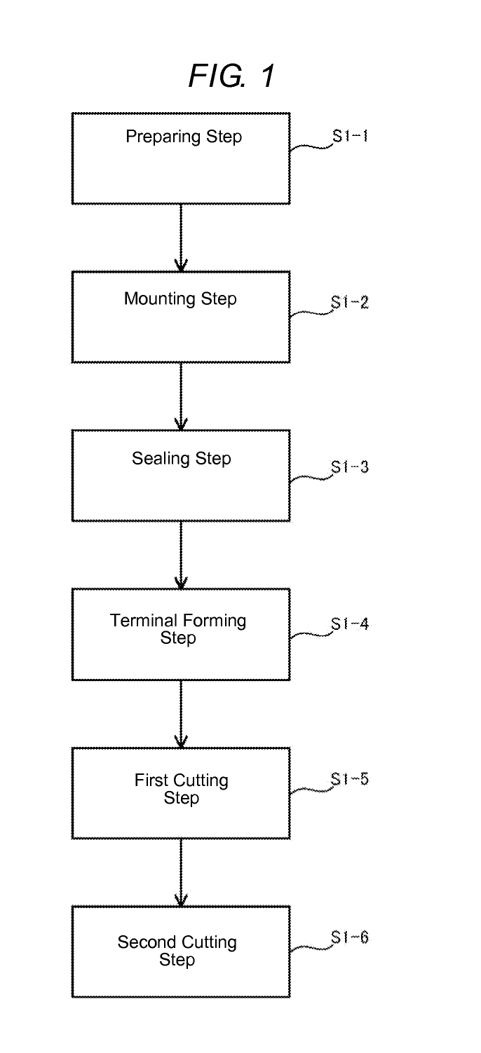

FIG. 1 is a flowchart illustrating a manufacturing method of a semiconductor device. The example of the manufacturing method of the semiconductor device illustrated in FIG. 1 at least includes a preparing step (S1-1), amounting step (S1-2), a sealing step (S1-3), a terminal forming step (S1-4), a first cutting step (S1-5), and a second cutting step (S1-6). The details of the respective steps and the order of implementation of the respective steps included in the example of the manufacturing method of the semiconductor device according to this embodiment are not required to be the same as those illustrated in FIG. 1.

The preparing step (S1-1) is a step for preparing a stacked body including a metal plate and semiconductor chips provided on a part of the metal plate. The stacked body has stacked structure with TSV system, for example. The stacked body is produced by laminating the plural semiconductor chips on the metal plate, and electrically connecting the respective semiconductor chips via through electrodes such as TSV's penetrating the semiconductor chips, for example.

The mounting step (S1-2) is a step for mounting the stacked body on a wiring substrate. In this step, the stacked body is electrically connected with the wiring substrate via bump electrodes provided on the upper surface of the stacked body, for example.

The sealing step (S1-3) is a step for forming a sealing resin layer on the wiring substrate. The sealing resin layer seals the stacked body. The sealing resin layer may be formed by transfer molding, compression molding, injection molding, or other molding methods, for example.

The terminal forming step (S1-4) is a step for forming external connection terminals. The external connection terminals may be formed from soldering balls provided on the wiring substrate, for example. When the semiconductor device is electrically connected with other electronic components via bonding wires or the like, the terminal forming step is not required to be implemented.

The first cutting step (S1-5) is a step for forming first cuts using a first dicing blade. This step forms first cuts reaching only an intermediate position of the sealing resin layer, and does not separate the respective wiring substrates into discrete pieces.

The second cutting step (S1-6) is a step for forming second cuts using a second dicing blade. This step separates the respective wiring substrates into discrete pieces. The first cutting step (S1-5) and the second cutting step (S1-6) may be combined and handled as one dicing step.

In addition to the foregoing steps, other steps may be performed in the manufacturing method, such as a marking step for marking product information including a product name on the devices, for example, a heating step, and a shield layer forming step for forming a shield layer which at least covers the shield resin layer on the semiconductor device containing marks thereon.

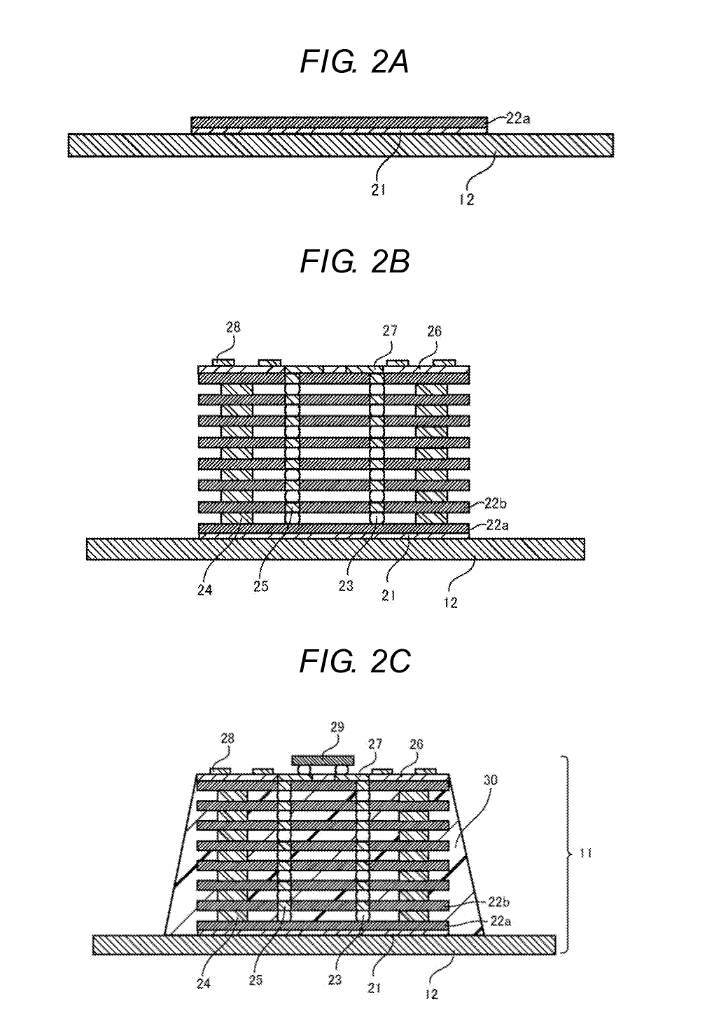

The respective steps are detailed with reference to the drawings. An example of a manufacturing method of a stacked body 11 prepared in the preparing step (S1-1) is herein discussed with reference to FIGS. 2A through 2C. FIGS. 2A through 2C are cross-sectional views illustrating the example of the manufacturing method of the stacked body 11.

As illustrated in FIG. 2A, a semiconductor chip 22a is bonded to a part of the upper surface of a metal plate 12 via a bonding layer 21. The metal plate 12 functions as a radiating plate which radiates heat generated within the semiconductor device toward the outside, for example. The metal plate 12 may be formed of a metal plate made of copper, iron, nickel or other metal, or alloys of these materials, for example. It is preferable, for example, that the metal plate 12 is configured as a copperplate in view of high heat conductivity. The bonding layer 21 may be formed by a resin film made of polyimide or epoxy, for example.

Subsequently, semiconductor chips 22b are stacked and connected as illustrated in FIG. 2B. A wiring layer 26 is formed on the uppermost semiconductor chip 22b. Electrode pads 28 are further provided on the wiring layer 26. In this example, a stacked body including the seven additional semiconductor chips 22b as shown in FIG. 2B is formed.

Each of the semiconductor chips 22b has through electrodes 25 such as TSV structures. The plural semiconductor chips 22b are bonded to each other via bonding layers 24, and electrically connected with each other via bump electrodes 23 and the through electrodes 25. The lowermost semiconductor chip 22b is bonded to the semiconductor chip 22a via the bonding layers 24 to be electrically connected with the semiconductor chip 22a via the bump electrodes 23 and the through electrodes 25. Each of the semiconductor chip 22a and the semiconductor chips 22b may be a memory chip, for example. The memory chip may be configured with a memory element such as NAND flash memory. The memory chip may contain a circuit such as a decoder. Through electrodes may be equipped in the semiconductor chip 22a to electrically connect the semiconductor chip 22a and the semiconductor chips 22b.

Each of the bump electrodes 23 may be configured with a metal bump or a soldering bump, for example. The soldering bump may be made of lead-free solder of the tin-silver family or the tin-silver-copper family, for example.

Specific examples of the wiring layer 26 involve a rewiring layer which repositions electrode pad connections on the semiconductor chip 22b. The wiring layer 26 is a rewiring layer provided on the semiconductor chip 22b, and includes connection wires 27. The connection wires 27 are electrically connected with the through electrodes 25 of the uppermost layer semiconductor chip 22b.

The connection wires 27 and the electrode pads 28 may be layers made of copper, titanium, titanium nitride, chromium, nickel, gold, palladium, or other material, for example.

Subsequently, a semiconductor chip 29 is positioned on the wiring layer 26 as illustrated in FIG. 2C. Then, sealing resin 30 is injected into clearances between the respective semiconductor chips 22b by under-filling or other methods. These processes now complete the stacked body 11.

The semiconductor chip 29 may be a flip-chip-type semiconductor chip, for example. The semiconductor chip 29 is electrically connected with the connection wires 27 via external connection terminals such as solder balls. The semiconductor chip 29 may be an interface chip or a controller chip, for example. When the semiconductor chips 22b are memory chips, for example, the semiconductor chip 29, when provided as a controller chip, for example, controls writing to and reading from the memory chips by the functioning of the controller chip. It is preferable that the semiconductor chip 29 is smaller than each of the semiconductor chips 22b. More specifically, it is preferable that the semiconductor 29 is formed on a part of the semiconductor chip 22b.

As discussed with reference to FIGS. 2A through 2C, the stacked body 11 includes the metal plate 12, the semiconductor chips (semiconductor chip 22a and semiconductor chips 22b) provided on a part of the metal plate 12, the wiring layer 26 provided on the semiconductor chip 22b and having the connection wires 27, and the semiconductor chip 29 provided on the wiring layer 26 and electrically connected with the semiconductor chips 22b via the connection wires 27. Each of the semiconductor chips 22b has the through electrodes 25 penetrating the chip so that the respective chips may be electrically connected with each other by the through electrodes 25. The stacked body 11 having the stacked structure with TSV system thus constructed decreases the chip area, and increases the number of connection terminals. These advantages may reduce poor connection and other problems. For producing the stacked body 11, the following method may be adopted. Initially, a plurality of the stacked bodies 11 are formed on the one metal plate 12. Then, the metal plate 12 is separated into pieces in correspondence with the stacked bodies 11 to produce the discrete stacked bodies 11.

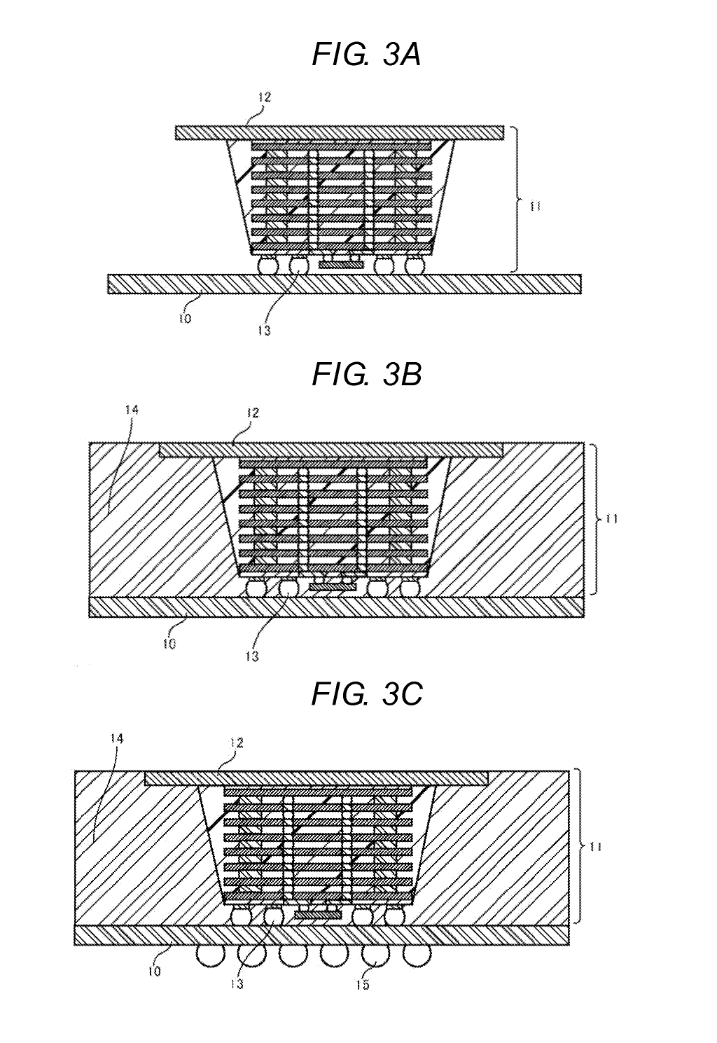

The details of the mounting step (S1-2), the sealing step (S1-3), and the terminal forming step (S1-4) are now discussed with reference to FIGS. 3A through 3C. FIGS. 3A through 3C are cross-sectional views illustrating the example of the manufacturing method of the semiconductor device. FIG. 3A illustrates the mounting step (S1-2). FIG. 3B illustrates the sealing step (S1-3). FIG. 3C illustrates the terminal forming step (S1-4).

In the mounting step (S1-2), the stacked body 11 is mounted on a first surface of a wiring substrate 10 so that the semiconductor chips are located on the first surface side of the wiring substrate 10 as illustrated in FIG. 3A. The stacked body 11 is electrically connected with the wiring substrate 10 via solder members 13 such as solder balls. For example, the stacked body 11 may be mounted by temporary bonding between the stacked body 11 and the wiring substrate 10, and then permanent bonding between the stacked body 11 and the wiring substrate 10 by reflow of the solder members 13.

The wiring substrate 10 may be formed by a resin substrate made of glass epoxy or the like and containing a wiring layer on the surface of the substrate, for example. The first surface of the wiring substrate 10 corresponds to the upper surface of the wiring substrate 10 in FIG. 3A, while a second surface of the wiring substrate 10 corresponds to the lower surface of the wiring substrate 10 in FIG. 3A. The first surface and the second surface of the wiring substrate 10 face away from each other.

In the sealing step (S1-3), a sealing resin layer 14 is formed on the first surface of the wiring substrate 10 as illustrated in FIG. 3B. The sealing resin layer 14 is so configured as to seal the stacked body 11. The sealing resin layer 14 may be produced by injection of sealing resin, for example. In the sealing step (S1-3), it is preferable that at least apart of the surface of the metal plate 12 is exposed. When the sealing resin is applied to the non-semiconductor chip side surface of the metal plate 12, the metal plate 12 may be exposed again by grinding or other methods to increase heat radiation from the semiconductor device.

The sealing resin may be made of material containing inorganic filler like SiO₂, such as material formed by a mixture of inorganic filler and insulating organic resin material like epoxy resin. The inorganic filler content of the whole sealing resin lies in the range from 80% to 95%. The inorganic filler has the function of controlling the viscosity, hardness, or other conditions of the sealing resin layer.

In the terminal forming step (S1-4), external connection terminals 15 are formed on the second surface of the wiring substrate 10 as in FIG. 3C. For example, a flux is applied to the second surface of the wiring substrate 10, and solder balls are mounted on the flux-applied second surface. The solder balls are melted in a reflow furnace to be joined to connection pads provided on the second surface of the wiring substrate 10. Then, the flux is removed by using a solvent or by washing with pure water, leaving in place the external connection terminals 15.

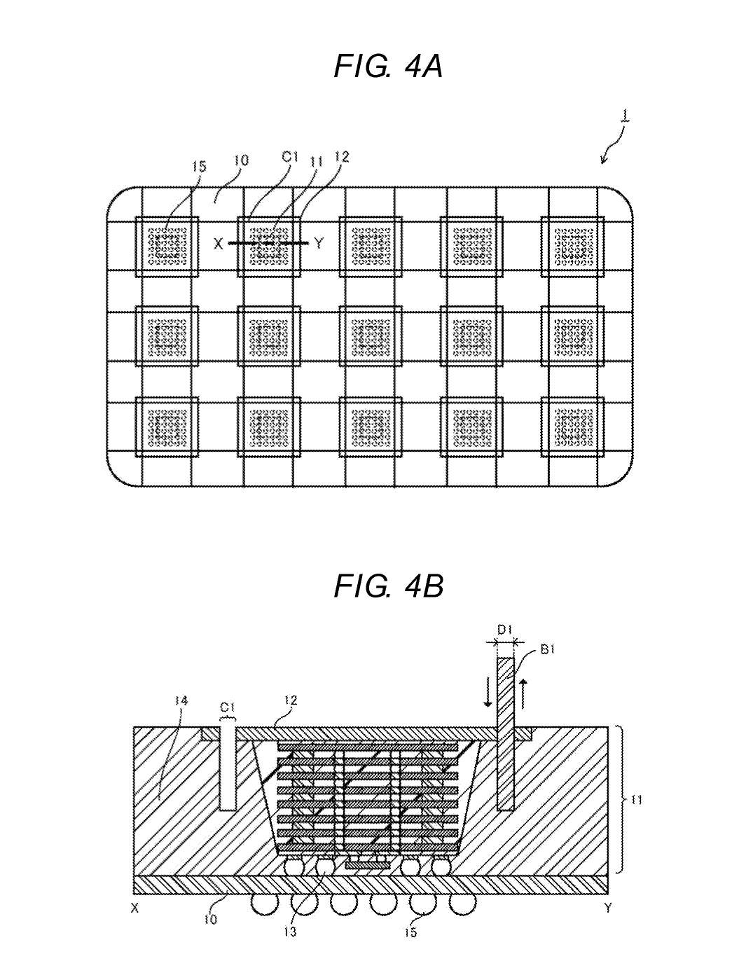

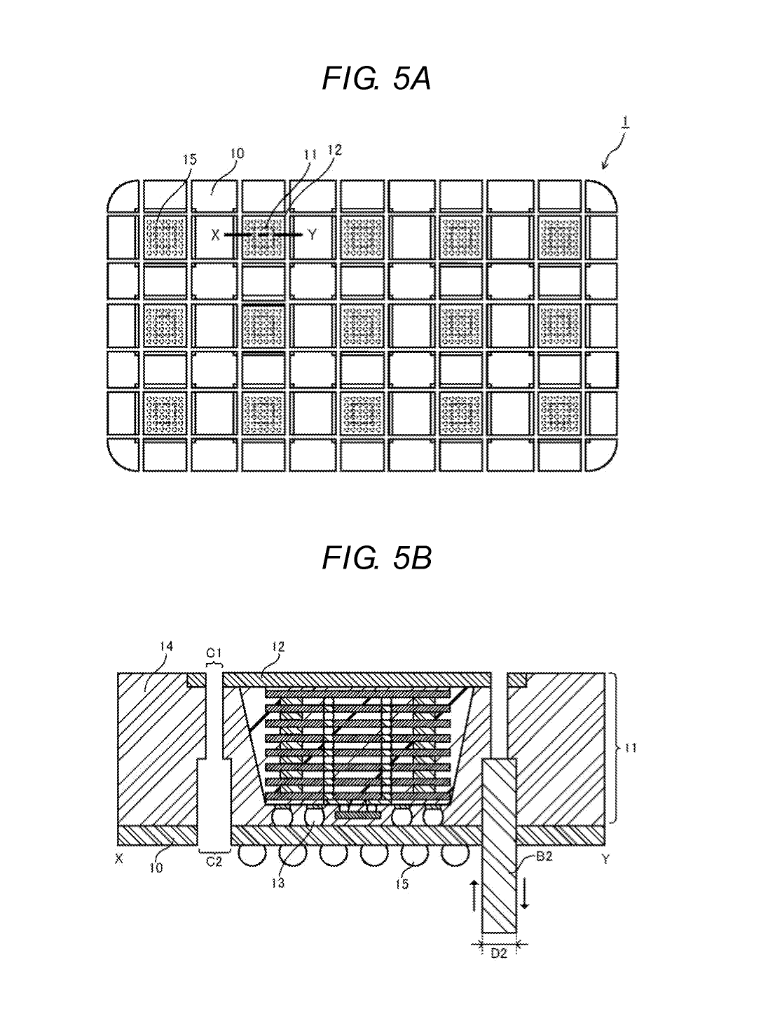

The first cutting step (S1-5) and the second cutting step (S1-6) are now described with reference to FIGS. 4A through 5B. Discussed in these steps is a method of separating an aggregate substrate 1 containing plural wiring substrates 10 spaced thereon in a matrix pattern.

FIGS. 4A and 4B illustrate the first cutting step (S1-5). FIG. 4A is a transparent top view of the aggregate substrate 1. FIG. 4B is a cross-sectional view taken along a line X-Y in FIG. 4A. In the first cutting step (S1-5), cuts C1 are formed using a dicing blade B1 to form cuts C1 surrounding each of the respective stacked bodies 11. In this step, the cuts C1 reaching the sealing resin layer 14 are formed with simultaneous cutting of the metal plates 12 (see FIGS. 4A and 4B). For example, the first cutting step (S1-5) is implemented with the wiring substrates 10 fixed to a dicing tape, a fixing jig or the like.

During this step, burrs are produced in the edges of the cuts C1. These burrs are projections corresponding to a part of the cutting target pressed out of the surface during the cutting process of the target using a dicing blade. Particularly, the metal plate 12 is ductile unlike the hard resin of sealing layer 14, which is chiefly made of inorganic filler such as SiO₂. Accordingly, when the metal plates 12 is cut, burrs are easily produced in the edges of the cuts C1 as a part of the metal plates 12 are pressed or pulled out of the surface of the metal plates at the cut surface.

According to the manufacturing method of the semiconductor device in this embodiment, cuts reaching only the intermediate position of the sealing resin layer 14 are formed with simultaneous cutting of the metal plates 12 from the metal plate 12 side in the first cutting step (S1-5). In this case, the wiring substrates 10 are not separated from each other. Accordingly, the metal plates 12 are cut while supported by the sealing resin layer 14 which is hard and chiefly made of inorganic filling material. Moreover, the cutting amount of the sealing resin layer 14 decreases. In that case, the amount of the cutting target pressed out of the surface decreases, and the amount of burrs decreases. It is preferable that the heights of burrs are 100 μm or smaller, for example. The wiring substrates 10 are made of material such as epoxy substrate, which is softer than the material of the metal plates 12. Thus, an extremely small amount of burrs or no burr develops in the sides or edges of the cuts C2 in the wiring substrate 10.

FIGS. 5A and 5B illustrate the second cutting step (S1-6). FIG. 5A is a transparent top view of the aggregate substrate 1. FIG. 5B is a cross-sectional view taken along a line X-Y in FIG. 5A. In the second cutting step (S1-6), the cuts C2 are formed using a dicing blade B2 to form cuts surrounding the stacked bodies 11. In this step, the cuts C2 reaching the previous cuts C1 complete a complete cutting through of the resin layer. The second cutting step (S1-6) thus separates the wiring substrates 10 into discrete pieces in correspondence with the stacked bodies 11. For example, the second cutting step (S1-6) may be implemented with the wiring substrates 10 fixed to a dicing tape, a fixing jig or the like. According to the example illustrated in FIGS. 5A and 5B and examples in other figures, the dicing blade B2 is inserted from below as viewed in the respective figures for convenience of illustration. However, it is preferable that the surfaces of the wiring substrates 10 are inverted and fixed after the first cutting step (S1-5), in which condition cutting of the cuts C2 is started.

Each of the dicing blade B1 and the dicing blade B2 may be a diamond blade, for example. In this case, the cutting target is brought into contact with a rotating diamond blade to form cuts. It is preferable that a thickness D1 of the dicing blade B1 is 0.2 mm or smaller, for example, and more preferably 0.15 mm or smaller. On the other hand, it is preferable that a thickness D2 of the dicing blade B2 is 0.3 mm or larger.

It is difficult to separate the wiring substrates 10 into pieces when the cuts C1 and the cuts C2 do not appropriately overlap with each other. However, positioning of the cuts C1 and the cuts C2 in alignment with each other is also difficult. When the dicing blade B1 and the dicing blade B2 are so configured that either the dicing blade B1 or the dicing blade B2 has a first thickness, and that the other of the dicing blade B1 and the dicing blade B2 has a second thickness larger than the first thickness, the cuts C1 and the corresponding cuts C2 easily overlap with each other at least partially even in the case of not completely overlapping with each other. In this condition, the wiring substrates 10 are easily separated.

The depth of the cuts C1 and the depth of the cuts C2 may be different. For example, when the cuts C1 and C2 are so formed that the cuts produced with simultaneous cutting of the wiring substrates 10 (cut C2 in FIG. 5B) have a first depth, and that the cuts produced with simultaneous cutting of the metal plates 12 (cut C1 in FIG. 5B) have a second depth smaller than the first depth, the cut amount of the resin sealing layer 14 is less during cutting of the metal plates 12 where burrs are easily produced. In this case, the amount of burrs will decrease. The decrease in the amount of burrs in this disclosure includes lowering of the heights of burrs.

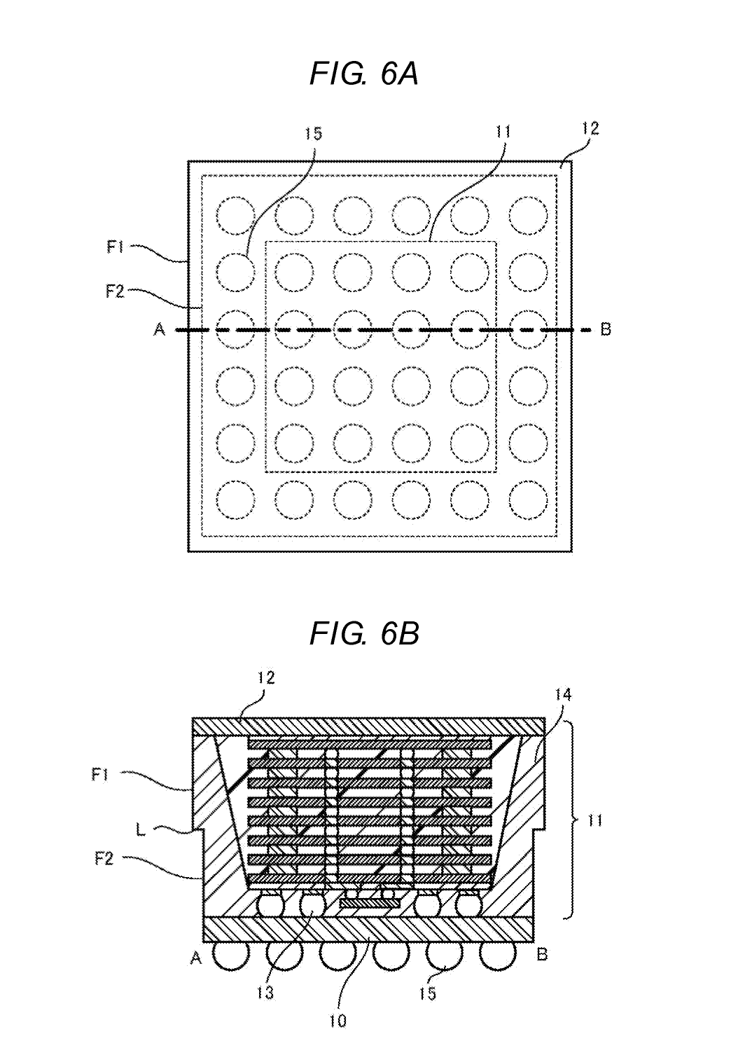

FIGS. 6A and 6B illustrate a structure example of a semiconductor device produced after the first cutting step (S1-5) and the second cutting step (S1-6). FIG. 6A is a top view, while FIG. 6B is a cross-sectional view taken along a line A-B in FIG. 6A. The semiconductor device illustrated in FIGS. 6A and 6B includes the wiring substrate 10 which contains a first surface and a second surface facing away from each other, the metal plate 12, and the semiconductor chips (semiconductor chips 22a, 22b, and 29) stacked on the metal plate 12. The semiconductor device contains the stacked body 11 provided on the first surface of the wiring substrate 10 so that the respective semiconductor chips are located on the first surface side of the wiring substrate 10, and the sealing resin layer 14 which seals the stacked body 11 disposed on the first surface of the wiring substrate 10 while allowing exposure of the second surface of the metal plate 12.

The semiconductor device further includes a side surface F1 continuously formed from the side surface of the metal plate 12 to a part of the side surface of the sealing resin layer 14 to surround the stacked body 11, and a side surface F2 continuously formed from the side surface of the wiring substrate 10 to a part of the side surface of the sealing resin layer 14 to surround the stacked body 11. The perimeter of side surface F1 of FIG. 6A is greater than the perimeter of side surface F2 of FIG. 6A. A step L is formed between the side surface F1 and the side surface F2. As discussed above, the amount of burrs decreases when the second depth is smaller than the first depth. Thus, the amount of burrs may be reduced by determining the distance between the step L and the metal plate 12 at a length shorter than the distance between the step L and the wiring substrate 10. The thickness of the semiconductor device may be set approximately in the range from 1.2 mm to 1.5 mm, for example. Burrs may be removed by grinding or other methods in a step subsequent to the second cutting step (S1-6).

According to this example, the cuts are formed from the metal plate 12 side in the first cutting step (S1-5), thereafter the cuts are formed from the wiring substrate 10 side in the second cutting step (S1-6). However, the cutting positions in the first cutting step (S1-5) and the second cutting step (S1-6) may be switched to the opposite sequence.

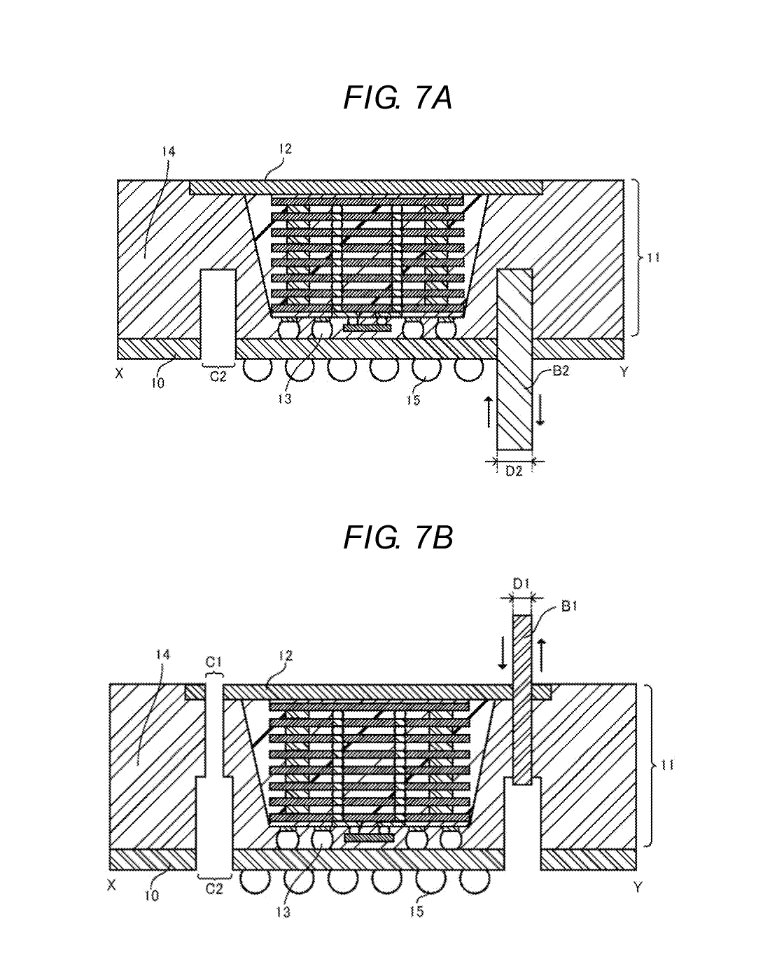

For example, FIGS. 7A and 7B are cross-sectional views illustrating another example of the manufacturing method of the semiconductor device. FIG. 7A is a cross-sectional view illustrating the first cutting step (S1-5), while FIG. 7B is a cross-sectional view illustrating the second cutting step (S1-6). This method contains parts similar to the corresponding parts in the manufacturing method of the semiconductor device described with reference to FIGS. 2A through 5B, and the explanation of the corresponding parts may be referred to for understanding of this example when appropriate.

As illustrated in FIG. 7A, the cuts C2 are formed using the dicing blade B2 to form cuts C2 surrounding the stacked bodies 11 in the first cutting step (S1-5). In this step, the cuts C2 reaching the sealing resin layer 14 are formed with simultaneous cutting of the wiring substrates 10. Then, as illustrated in FIG. 7B, the cuts C1 are formed using the dicing blade B1 to surround the stacked bodies 11 in the second cutting step (S1-6). This step separates the wiring substrates 10 into discrete pieces in correspondence with the stacked bodies 11. In this step, the cuts C1 reaching the cuts C2 are formed with simultaneous cutting of the metal plates 12. Accordingly, the manufacturing method of the semiconductor device in this embodiment may switch the positions of the cuts in the first cutting step (S1-5) and the second cutting step (S1-6) to the opposite sequence.

As illustrated in FIGS. 4A through 5B, the dicing blade B1 is used in the first cutting step (S1-5), and the dicing blade B2 having a thickness larger than that of the dicing blade B1 is used in the second cutting step (S1-6). However, the dicing blades used in the first cutting step (S1-5) and the second cutting step (S1-6) may be switched to the opposite blades.

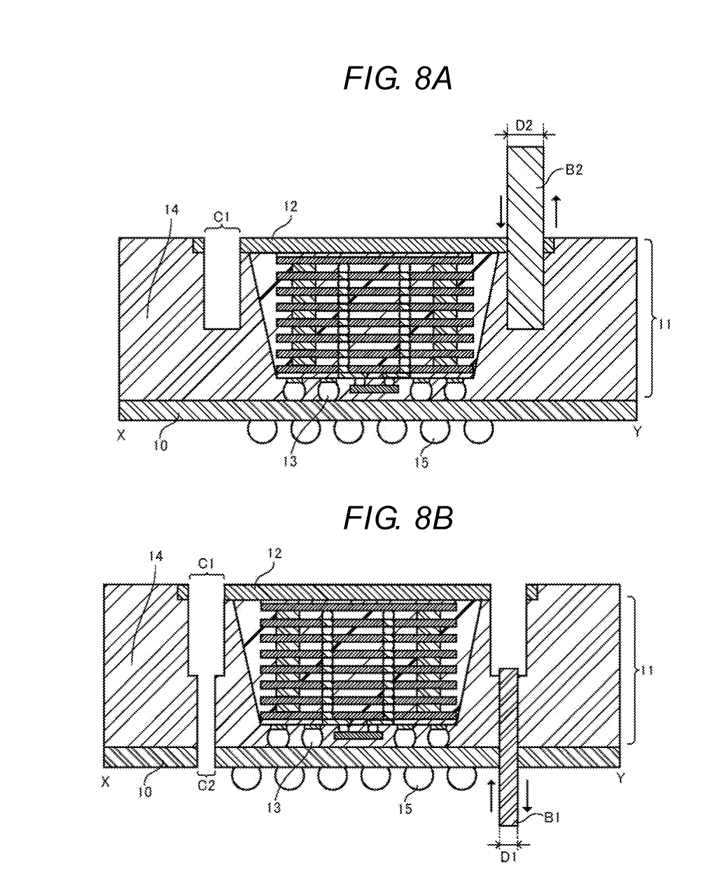

For example, FIGS. 8A and 8B are cross-sectional views illustrating a further example of the manufacturing method of the semiconductor device. FIG. 8A is a cross-sectional view illustrating the first cutting step (S1-5), while FIG. 8B is a cross-sectional view illustrating the second cutting step (S1-6). This method contains parts similar to the corresponding parts in the manufacturing method of the semiconductor device described with reference to FIGS. 2A through 5B, and the explanation of the corresponding parts may be referred to for understanding of this example when appropriate.

As illustrated in FIG. 8A, the cuts C1 are formed using the dicing blade B2 to form cuts C1 surrounding the stacked bodies 11 in the first cutting step (S1-5). In this step, the cuts C1 reaching the sealing resin layer 14 are formed with simultaneous cutting of the metal plates 12. Then, as illustrated in FIG. 8B, the cuts C2 are formed using the dicing blade B1 to form cuts C2 surrounding the stacked bodies 11 in the second cutting step (S1-6) and these cuts C2 also penetrate the bases of the earlier cuts C1. This step separates the wiring substrates 10 into discrete pieces in correspondence with the stacked bodies 11. In this step, the cuts C2 reaching the cuts C1 are formed with simultaneous cutting of the wiring substrates 10. Accordingly, the manufacturing method of the semiconductor device in this embodiment may switch the dicing blades used in the first cutting step (S1-5) and the second cutting step (S1-6) to the opposite blades.

According to this embodiment, the dicing step is divided into the first cutting step and the second cutting step. In this case, the amount of burrs produced at the time of cutting of the metal plates decreases. Accordingly, problems such as increases in the thickness of the semiconductor package, and the formation of short circuits, decrease.

### Second Embodiment

Discussed in this embodiment is a manufacturing method of a semiconductor device implemented in an order different from the order of the method in the first embodiment.

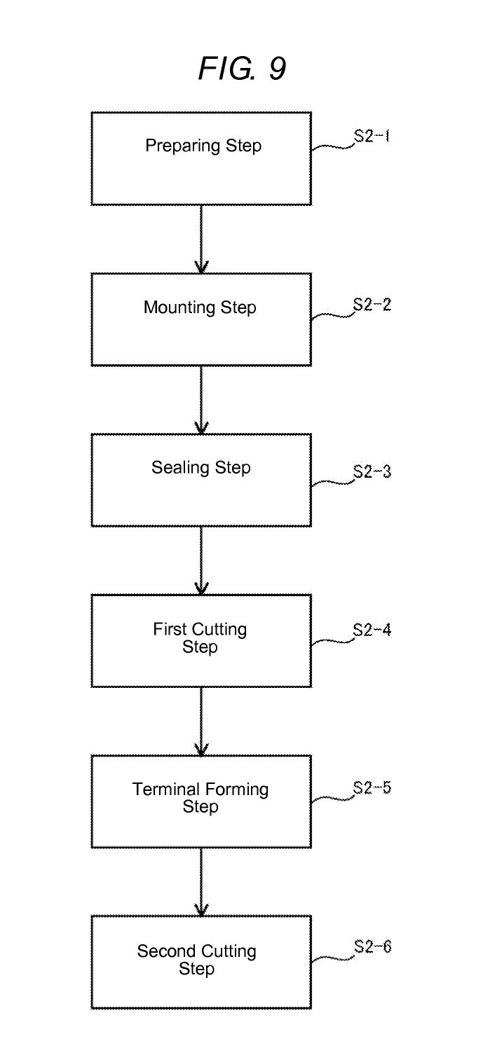

FIG. 9 is a flowchart illustrating an example of a manufacturing method of a semiconductor device. The example of the manufacturing method of the semiconductor device illustrated in FIG. 9 at least includes a preparing step (S2-1), a mounting step (S2-2), a sealing step (S2-3), a first cutting step (S2-4), a terminal forming step (S2-5), and a second cutting step (S2-6). The preparing step (S2-1) corresponds to the preparing step (S1-1) in FIG. 1. The mounting step (S2-2) corresponds to the mounting step (S1-2) in FIG. 1. The sealing step (S2-3) corresponds to the sealing step (S1-3) in FIG. 1. Accordingly, the explanation of the corresponding parts included in the manufacturing method of the semiconductor device in the first embodiment may be referred to for understanding of the preparing step (S2-1) through the sealing step (S2-3) when appropriate.

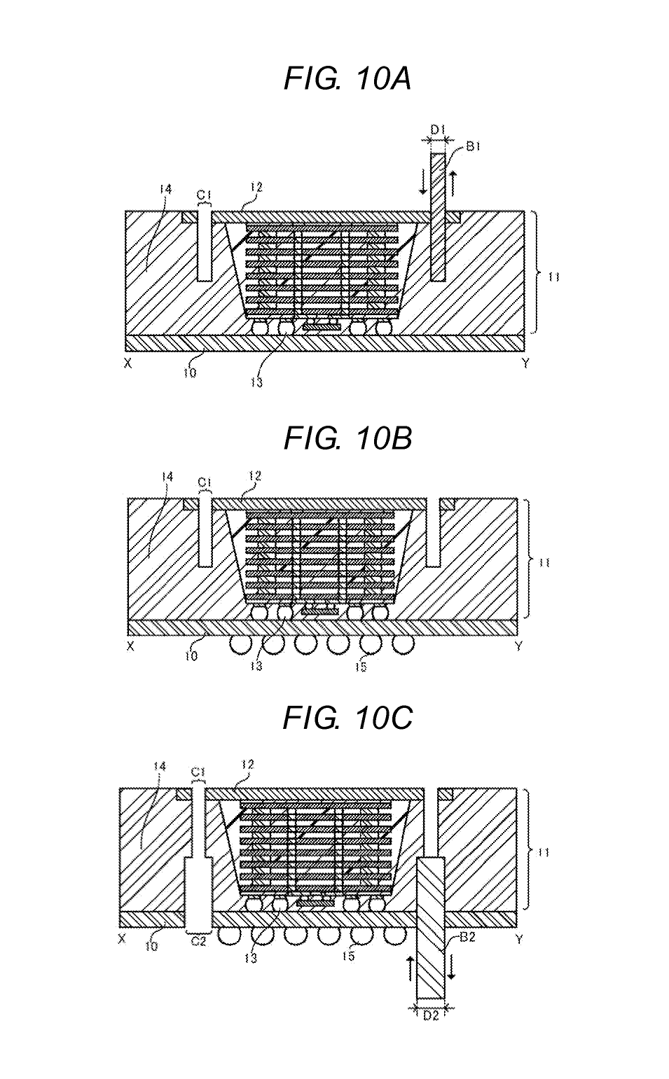

The first cutting step (S2-4), the terminal forming step (S2-5), and the second cutting step (S2-6) are hereinafter described with reference to FIGS. 10A through 10C.

FIGS. 10A through 10C illustrate the manufacturing method of the semiconductor device according to this embodiment. FIG. 10A is a cross-sectional view illustrating the first cutting step (S2-4). FIG. 10B is a cross-sectional view illustrating the terminal forming step (S2-5). FIG. 10C is a cross-sectional view illustrating the second cutting step (S2-6).

As illustrated in FIGS. 10A and 10B, an example of the semiconductor device produced by the preparing step (S2-1) through the sealing step (S2-3) includes the wiring substrate 10 which contains the first surface and the second surface facing away from each other, the metal plate 12, the stacked body 11 stacked on a part of the metal plate 12 and containing the semiconductor chips, and the sealing resin layer 14 sealing the stacked body 11. The explanation of the corresponding parts in the structure of the semiconductor device described with reference to FIGS. 2A through 5B may be referred to for understanding of this embodiment when appropriate.

In the first cutting step (S2-4), the cuts C1 are formed using the dicing blade B1 to form cuts C1 surrounding the stacked bodies 11 as illustrated in FIG. 10A. In this step, the cuts C1 reaching the sealing resin layer 14 are formed with simultaneous cutting of the metal plates 12 (see FIG. 10A).

In the terminal forming step (S2-5), the external connection terminals 15 are formed on the second surface of the wiring substrate 10 as illustrated in FIG. 10B after the cuts C1 have been made. The explanation of the external connection terminals 15 in the first embodiment may be referred to for understanding of the external connection terminals 15 in this embodiment.

In the second cutting step (S2-6), the cuts C2 are formed using the dicing blade B2 to form cuts C2 surrounding the stacked bodies 11 as illustrated in FIG. 10C. In this step, the cuts C2 reaching the cuts C1 are formed with simultaneous cutting of the wiring substrates 10. The second cutting step (S2-6) separates the wiring substrates 10 into discrete pieces in correspondence with the stacked bodies 11. The explanation of the dicing blade B1 and the dicing blade B2 with reference to FIGS. 4A through 5B may be referred to for understanding of the dicing blade B1 and the dicing blade B2 in this embodiment.

The manufacturing method of the semiconductor device according to this embodiment implements the first cutting step before the terminal forming step (S2-5). Accordingly, in the first cutting step (S2-4), the surface area of the dicing tape, a fixing jig or the like to be attached to the wiring substrates 10 may be increased upon fixation between the substrates 10 and the dicing tape, fixing jig or the like, because the terminals 15 are not present. Moreover, since the metal plates 12 are cut in the first cutting step (S2-4), in the second cutting step (S2-6) the surface where the external connection terminals 15 have been formed may be positioned on the side opposite to the fixing surface side. Therefore, it is possible to use the same fixing jig or the like as that used in the first cutting step (S2-5) for fixation in the second cutting step (S2-6).

Similarly to the first embodiment, the dicing blades used in the first cutting step (S2-5) and the second cutting step (S2-6) may be switched to the opposite dicing blades. In addition, the depths of the cuts C1 and the cuts C2 may be different similarly to the first embodiment.

According to this embodiment, therefore, a part of the dicing step (first cutting step) is implemented before formation of the external connection terminals on the wiring substrates. This method reduces burrs, and increases the stability during dicing. After this cutting step, the remaining part of the dicing step (second cutting step) is implemented. Accordingly, separation of the chips from a dicing tape or the like during dicing is avoided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
mounting a stacked body on a first surface of a wiring substrate, the stacked body including a metal plate and semiconductor chips stacked on a part of the metal plate, so that the semiconductor chips are located on the first surface side of the wiring substrate;
forming a sealing resin layer sealing the stacked body on the first surface of the wiring substrate;
forming a first cut reaching the sealing resin layer using a first dicing blade while also cutting through either the metal plate or the wiring substrate, so that the first cut surrounds the stacked body; and
forming a second cut reaching the first cut using a second dicing blade while cutting through the other of the metal plate and the wiring substrate to separate the wiring substrate in correspondence with the stacked body, so that the second cut surrounds the stacked body.

2. The method according to claim 1, wherein
an external connection terminal is formed on a second surface facing away from the first surface of the wiring substrate at least before forming the second cut.

3. The method according to claim 2, wherein an external connection terminal is formed on a second surface facing away from the first surface of the wiring substrate after forming the first cut.

4. The method according to claim 3, wherein the first cut cuts through the wiring substrate.

5. The method according to claim 3, further comprising mounting the wiring substrate in a carrier;
forming the first cut reaching the sealing resin layer using a first dicing blade while also cutting through either the metal plate;
removing the wiring substrate from the carrier;
positioning the cut surface of the metal plate in the carrier; and
forming the second cut reaching the first cut and cutting through the wiring substrate.

6. The method according to claim 5, further comprising forming the terminals on the second surface of the wiring substrate after forming the first cuts in the resin layer and through the metal plate.

7. The method according to claim 1, wherein
either the first dicing blade or the second dicing blade has a first thickness, and
the other of the first dicing blade and the second dicing blade has a second thickness larger than the first thickness.

8. The method according to claim 1, wherein
the first cut or the second cut, which is formed when cutting through the wiring substrate, has a first depth, and
the first cut or the second cut, which is formed when cutting through the metal plate, has a second depth smaller than the first depth.

9. The method according to claim 1, wherein the sidewall of one of the first cut or the second cut is closer to the stacked body than the other of the first cut and the second cut, and a step portion is left on a side of the semiconductor device.

10. The method according to claim 1, further comprising after making the first cut and the second cut, grinding the cut surface of the metal plate.

11. A semiconductor device, comprising:
a wiring substrate including a first surface, and a second surface facing away from the first surface;
a stacked body including a metal plate and semiconductor chips stacked on the metal plate, mounted on a first surface side of the wiring substrate with the semiconductor chips located on the first surface side of the wiring substrate;
a sealing resin layer sealing the stacked body disposed on the first surface of the wiring substrate, with at least a part of the metal plate exposed to the exterior of the resin layer;
a first side surface continuously formed from a side surface of the metal plate to a part of a side surface of the sealing resin layer and surrounding the stacked body; and
a second side surface continuously formed from a side surface of the wiring substrate to a part of the side surface of the sealing resin layer and surrounding the stacked body,
wherein a step is formed between the first side surface and the second side surface.

12. The semiconductor device of claim 11, wherein the perimeter of the first side surface is greater than the perimeter of the second side surface.

13. The semiconductor device of claim 11, wherein the depth of the first side surface from the metal plate to the step is less than the depth of the side surface from the wiring substrate to the step.

14. The semiconductor device of claim 11, wherein the depth of the first side surface from the metal plate to the step is greater than the depth of the side surface from the wiring substrate to the step.

15. The semiconductor device of claim 11, further comprising external connection terminals on the second surface of the wiring substrate.

16. A method of forming a semiconductor device having a plurality of semiconductor chips interconnected to one another and bonded to a metal plate to form a stacked body, comprising;
providing a wiring substrate having a first surface and a second, opposed surface;
providing a plurality of patterns of solder connections on the first surface
positioning a stacked body in contact with each of the plurality of patterns of solder connections on the first surface such that the semiconductor chips are positioned between the metal plate and the wiring substrate;
heating the stacked body, the wiring substrate, or both and reflowing the solder connections to electrically connect the stacked bodies to the wiring substrate;
encapsulating the wiring substrate and the stacked bodies in a sealing resin, such that a surface of the metal plate is uncovered by the sealing resin;
cutting first grooves across the plurality or metal plates or the wiring substrate to either side of a plurality of stacked bodies and into the sealing layer in a first direction;
cutting second grooves across the plurality or metal plates or the wiring substrate to either side of a plurality of stacked bodies in a second direction generally orthogonal to the first direction and to either side of the stacked bodies and into the sealing resin, and intersecting the first groove;
cutting third grooves across the other of the plurality of metal plates or the wiring substrate to either side of a plurality of stacked bodies and into the sealing layer in a first direction, and into the first grooves previously cut into the first direction; and
cutting fourth grooves across the other of the plurality of metal plates or the wiring substrate to either side of a plurality of stacked bodies in a second direction generally orthogonal to the first direction and to either side of the stacked bodies and into the sealing resin and intersecting the third grooves, and into the second grooves previously cut in the second direction, thereby singulating a plurality of semiconductor devices.

17. The method of claim 16, further comprising grinding the surface of the metal plate which was cut while forming the grooves.

18. The method of claim 16, further comprising forming terminals on the second surface of the wiring substrate after forming grooves in the first direction and the second direction through the metal plates and before cutting grooves through the wiring substrate.

19. The method of claim 18, further comprising cutting the grooves in the first and second direction and through the metal plates and into the sealing resin to a depth shallower than the grooves cut through the wiring substrate and into the sealing resin.

20. The method of claim 16, further comprising cutting narrow grooves in the first and second direction and through the metal plates and into the sealing resin and broader grooves through the wiring substrate and into the sealing resin in the first and second direction.
